(19) United States
(12) Patent Application Publication
(10) Pub. No.: US 2026/0082952 A1
(43) Pub. Date: Mar. 19, 2026

(54) ELECTRONIC COMPONENT MODULE

(71) Applicant: Murata Manufacturing Co., Ltd., Kyoto-fu (JP)

(72) Inventor: Yoshiki NAKAGAWA, Nagaokakyo-shi (JP)

(73) Assignee: Murata Manufacturing Co., Ltd., Kyoto-fu (JP)

(21) Appl. No.: 19/400,101

(22) Filed: Nov. 25, 2025

Related U.S. Application Data
(63) Continuation of application No. PCT/JP2024/017397, filed on May 10, 2024.

(30) Foreign Application Priority Data
Jun. 13, 2023 (JP) 2023-096991

(51) Int. Cl. H01L 23/538; H01L 23/00; H01L 23/64; H01L 25/16

(52) U.S. Cl. CPC H10W 70/614; H10W 44/501; H10W 70/611; H10W 70/685; H10W 90/00; H10W 90/724

(57) ABSTRACT

An electronic component module includes an electronic component and a multilayer wiring board. The multilayer wiring board includes wiring layers and insulating layers. A disposition surface has a hole. The wiring layers include a front surface wiring layer configuring the disposition surface and a bottom surface wiring layer configuring a bottom surface of the hole. The electronic component includes an electric circuit, an outer contour portion defining an outer contour of the electronic component, and an electrode connecting the electric circuit and the wiring layers. The outer contour portion includes an outer contour portion body on the front surface wiring layer, a first facing surface facing the front surface wiring layer, a projection in the hole, and a second facing surface defining an end surface in a first direction of the projection and facing the bottom surface wiring layer.

### CROSS-REFERENCE TO RELATED APPLICATIONS

This application claims benefit of priority to International Patent Application No. PCT/JP2024/017397, filed May 10, 2024, and to Japanese Patent Application No. 2023-096991, filed Sep. 13, 2023, the entire contents of each are incorporated herein by reference.

### BACKGROUND

### Technical Field

The present disclosure relates to an electronic component module.

### Background Art

An electronic component module includes a substrate including a surface provided with wiring, and a plurality of electronic components mounted on the surface of the substrate. An electronic component module according to Japanese Unexamined Patent Application Publication No. 11-135566 includes a substrate including a surface provided with a hole. The hole accommodates an electronic component (semiconductor bare chip). That is, the electronic component does not project from the surface of the substrate. This enables a thickness reduction (size reduction) of the electronic component module.

### SUMMARY

However, the technique according to Japanese Unexamined Patent Application Publication No. 11-135566 restricts the electronic component in size so as to be accommodated in the hole. Such circumstances raise a need for development of an electronic component module that can be reduced in size even if an electronic component is larger than a hole.

The present disclosure has been achieved in view of the above, and provides an electronic component module that can be reduced in size.

An electronic component module according to the present disclosure includes an electronic component, and a multilayer wiring board disposed in a first direction of the electronic component and including a surface positioned in a second direction opposing the first direction as a disposition surface provided with the electronic component. The multilayer wiring board includes a plurality of wiring layers and a plurality of insulating layers stacked alternately in the first direction. The disposition surface is provided with a hole. The plurality of wiring layers includes a front surface wiring layer constituting the disposition surface and a bottom surface wiring layer constituting a bottom surface of the hole. The electronic component includes an electric circuit, an outer contour portion containing the electric circuit and forming an outer contour of the electronic component, and an electrode provided on an outer surface of the outer contour portion and connecting the electric circuit and the wiring layers. The outer contour portion includes an outer contour portion body disposed on the front surface wiring layer, a first facing surface constituting a surface in the first direction of the outer contour portion body and facing the front surface wiring layer, a projection projecting in the first direction from the outer contour portion body and disposed in the hole, and a second facing surface constituting an end surface in the first direction of the projection and facing the bottom surface wiring layer. The electrode includes a first electrode provided on the first facing surface and connected to the front surface wiring layer, and a second electrode provided on the second facing surface and connected to the bottom surface wiring layer.

The electronic component module is reduced in size in the present disclosure.

### BRIEF DESCRIPTION OF THE DRAWING

FIG. 1 is a plan view of an electronic component module according to a first embodiment;

FIG. 2 is a schematic view of a section taken along line II-II in FIG. 1;

FIG. 3 is a schematic view of a section taken along line III-III in FIG. 1;

FIG. 4 is a plan view from a second direction of a multilayer wiring board according to the first embodiment;

FIG. 5 is a plan view from a first direction of a filter device (electronic component) according to the first embodiment;

FIG. 6 is a sectional view of an electronic component module according to a second embodiment, taken along an imaginary plane extending in a stacking direction and an array direction; and

FIG. 7 is a view from a direction opposing a second facing surface, of an electronic component according to a variation.

### DETAILED DESCRIPTION

Detailed description is made hereinafter to power amplifiers according to embodiments of the present disclosure with reference to the drawings. These embodiments do not limit the present disclosure. The embodiments are provided exemplarily, and any partial replacement or any combination is obviously applicable between configurations exemplified in different embodiments. After description of a first embodiment, only different features will be described without repeatedly describing features in common with a second embodiment. In particular, identical or similar functional effects achieved by an identical or similar configuration will not be referred to in each embodiment.

### First Embodiment

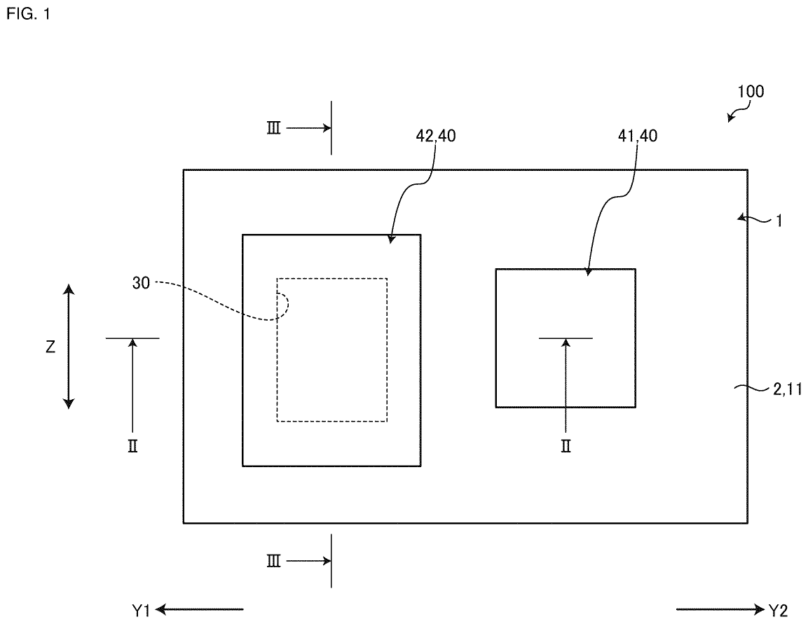

FIG. 1 is a plan view of an electronic component module according to the first embodiment. An electronic component module 100 according to the first embodiment includes a multilayer wiring board 1 and two electronic components 40. The two electronic components 40 include an integrated circuit 41 and a filter device 42. The integrated circuit 41 and the filter device 42 are disposed on an identical planar surface (front surface 2) of the multilayer wiring board 1.

Hereinafter, a direction parallel to the front surface 2 will be referred to as a planar direction. The planar direction includes an array direction in which the integrated circuit 41 and the filter device 42 are aligned. The array direction includes a first array direction Y1 in which the filter device 42 is disposed when viewed from the integrated circuit 41, and a second array direction Y2 opposing the first array direction Y1. The planar direction also includes a width direction Z crossing the array direction.

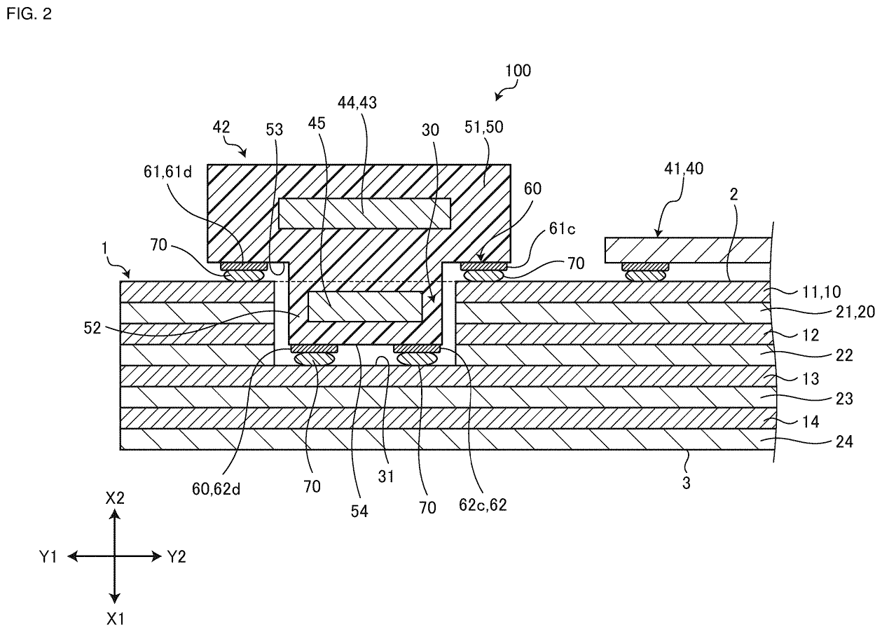

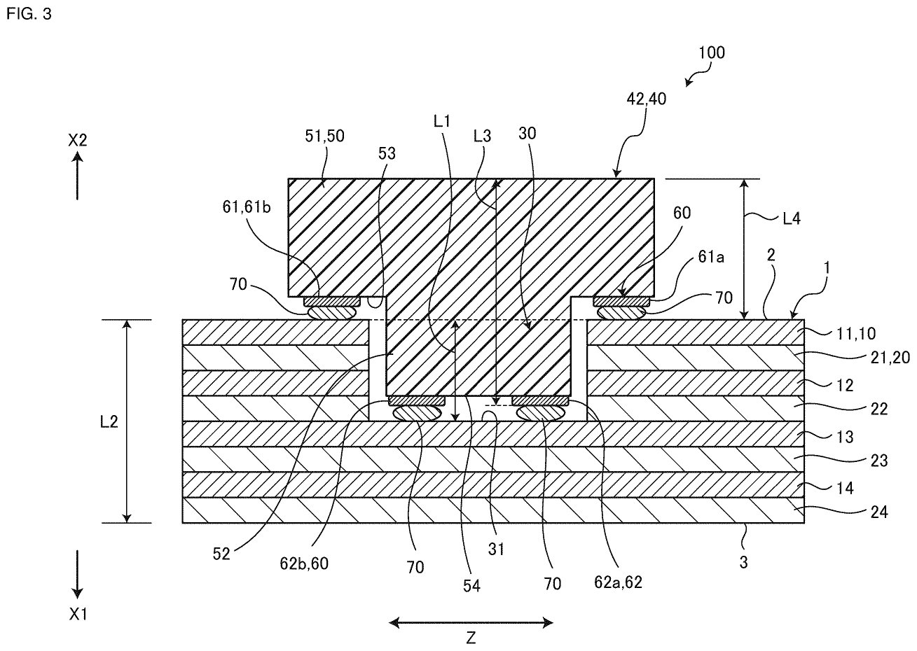

FIG. 2 is a schematic view of a section taken along line II-II in FIG. 1. FIG. 3 is a schematic view of a section taken along line III-III in FIG. 1. As shown in FIGS. 2 and 3, the multilayer wiring board 1 includes a plurality of wiring layers 10 and a plurality of insulating layers 20 stacked alternately. FIGS. 2 and 3 show sections of the wiring layers 10 and the insulating layers 20 provided continuously in the planar direction for easier comprehension of a structure of the multilayer wiring board 1, although the sections are actually provided intermittently in the planar direction.

Hereinafter, assume that the wiring layers 10 and the insulating layers 20 are stacked in a stacking direction. The stacking direction includes a first direction X1 in which the multilayer wiring board 1 is disposed when viewed from the filter device 42, and a second direction X2 opposing the first direction.

The multilayer wiring board 1 includes the front surface 2 facing in the second direction X2 and a rear surface 3 facing in the first direction X1. The front surface 2 is provided with the electronic components 40. The rear surface 3 is provided with no electronic component.

The wiring layers 10 and the insulating layers 20 each include four layers. That is, the plurality of wiring layers 10 includes a first wiring layer 11, a second wiring layer 12, a third wiring layer 13, and a fourth wiring layer 14. The plurality of insulating layers 20 includes a first insulating layer 21, a second insulating layer 22, a third insulating layer 23, and a fourth insulating layer 24.

The first wiring layer 11, the first insulating layer 21, the second wiring layer 12, the second insulating layer 22, the third wiring layer 13, the third insulating layer 23, the fourth wiring layer 14, and the fourth insulating layer 24 are stacked in the mentioned order in a first direction Z1. Accordingly, the first wiring layer 11 serves as a disposition layer provided with the electronic components 40 and constitutes the front surface 2. The fourth insulating layer 24 constitutes the rear surface 3.

The front surface 2 of the multilayer wiring board 1 is provided with a hole 30. As shown in FIG. 3, the hole 30 has a depth L1 smaller than a thickness L2 in the stacking direction of the multilayer wiring board 1. That is, the hole 30 does not penetrate the multilayer wiring board 1. Each of the first wiring layer (front surface wiring layer) 11, the first insulating layer 21, the second wiring layer 12, and the second insulating layer 22 is partially penetrated by the hole 30. The third wiring layer (bottom surface wiring layer) 13 constitutes a bottom surface 31 of the hole 30.

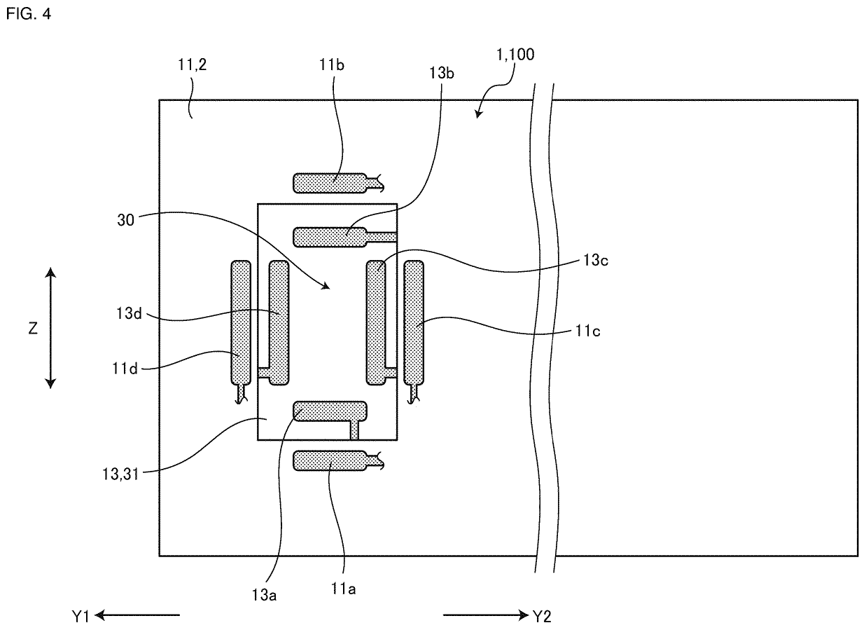

FIG. 4 is a plan view from the second direction of the multilayer wiring board according to the first embodiment. As shown in FIG. 4, when viewed from the second direction X2, the hole 30 has an oblong shape and is longer in the width direction Z than in the array direction.

The first wiring layer 11 includes an end portion 11a of a first wiring line, an end portion 11b of a second wiring line, and end portions 11c and 11d of two ground wiring lines, and the end portions are disposed around an edge of the hole 30. The third wiring layer 13 includes an end portion 13a of a third wiring line, an end portion 13b of a fourth wiring line, and end portions 13c and 13d of two ground wiring lines, and the end portions are disposed on the bottom surface 31.

The filter device 42 is configured to restrict a band of a received electrical signal. As shown in FIG. 2, the filter device 42 includes an electric circuit 43, an outer contour portion 50 containing the electric circuit 43, and an electrode 60 provided on an outer surface of the outer contour portion 50. As shown in FIG. 3, the filter device 42 has a height (size in the stacking direction) L3 larger than the depth L1 (see FIG. 3) of the hole 30 (L3>L1). That is, the filter device 42 is larger than the hole 30. Note that FIG. 3 does not show the electric circuit 43.

As shown in FIG. 2, the electric circuit 43 includes a first LC filter (first electric circuit) 44, and a second LC filter (second electric circuit) 45. The filter device 42 according to the present embodiment thus has two functions. In other words, the filter device 42 is obtained by combining (integrating) two filter devices. The first LC filter 44 and the second LC filter 45 are different in pass band from each other in the present embodiment. The first LC filter 44 and the second LC filter 45 may alternatively be identical in pass band in the present disclosure.

The outer contour portion 50 includes an outer contour portion body 51, and a projection 52 projecting in the first direction X1 from the outer contour portion body 51. The outer contour portion 50 is made of a resin material. The outer contour portion body 51 and the projection 52 are thus integrated so as not to be isolated from each other. The outer contour portion body 51 and the projection 52 are each formed into a cubic shape. The outer contour portion 50 according to the present disclosure may be applied to a ceramic package.

The outer contour portion body 51 is disposed on the front surface 2 (first wiring layer 11). The outer contour portion body 51 includes a first facing surface 53 facing in the first direction X1. The first facing surface 53 faces the front surface 2 (first wiring layer 11). The projection 52 is accommodated in the hole 30. The projection 52 includes an end surface in the first direction X1 serving as a second facing surface 54 facing the bottom surface 31 (third wiring layer 13) of the hole 30.

In FIG. 2, the first LC filter 44 is disposed in the outer contour portion body 51 and the second LC filter 45 is disposed in the projection 52. However, the present disclosure is not limited to the disposition. The first LC filter 44 may be exemplarily disposed in both the outer contour portion body 51 and the projection 52, without any limitation on positioning of the electric circuit disposed in the outer contour portion 50.

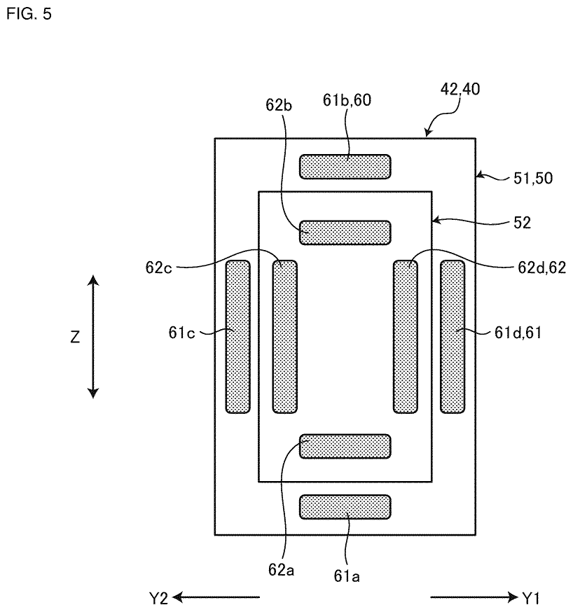

FIG. 5 is a plan view from the first direction of the filter device (electronic component) according to the first embodiment. As shown in FIG. 5, the projection 52 is disposed in the center of the first facing surface 53. The first facing surface 53 thus has a rectangular frame shape (annular shape). The second facing surface 54 has an oblong shape. The electrode 60 includes a first electrode 61 provided on the first facing surface 53 and a second electrode 62 provided on the second facing surface 54.

The first electrode 61 is provided to connect the first LC filter 44 and the first wiring layer (front surface wiring layer) 11. The first electrode 61 is joined to the first wiring layer 11 by solder 70 (see FIGS. 2 and 3). The first electrode 61 includes an input electrode 61a (see FIG. 3) joined to the end portion 11a, an output electrode 61b (see FIG. 3) joined to the end portion 11b, and two ground electrodes 61c and 61d (see FIG. 2) joined to the end portions 11c and 11d.

The second electrode 62 is provided to connect the second LC filter 45 and the third wiring layer (bottom surface wiring layer) 13. The second electrode 62 is joined to the third wiring layer 13 by solder 70 (see FIGS. 2 and 3). The second electrode 62 includes an input electrode 62a (see FIG. 3) joined to an end portion 31a, an output electrode 62b (see FIG. 3) joined to an end portion 31b, and two ground electrodes 62c and 62d (see FIG. 2) joined to end portions 31c and 31d.

As described above, the electronic component 40 (filter device 42) is partially accommodated in the hole 30 in the first embodiment. The electronic component 40 (filter device 42) projecting in the second direction X2 from the front surface 2 accordingly has a small projecting amount L4 (see FIG. 3). That is, the electronic component module 100 is reduced in size even when the electronic component 40 (filter device 42) is larger than the hole 30.

The filter device 42 has the two functions (the first LC filter 44 and the second LC filter 45). Provision of two components (an electronic component including the first LC filter 44 and an electronic component including the second LC filter 45) will lead to an increase in the number of components. Furthermore, the two components will be disposed on the front surface 2 to occupy a large area on the front surface 2. The present embodiment thus avoids such an increase in the number of components. Furthermore, the filter device 42 occupies a small area on the front surface 2. The electronic component module 100 can thus be reduced in size in the planar direction.

The first embodiment has been described above. The following second embodiment will describe an exemplary case where the electronic components 40 are provided on the rear surface 3.

### Second Embodiment

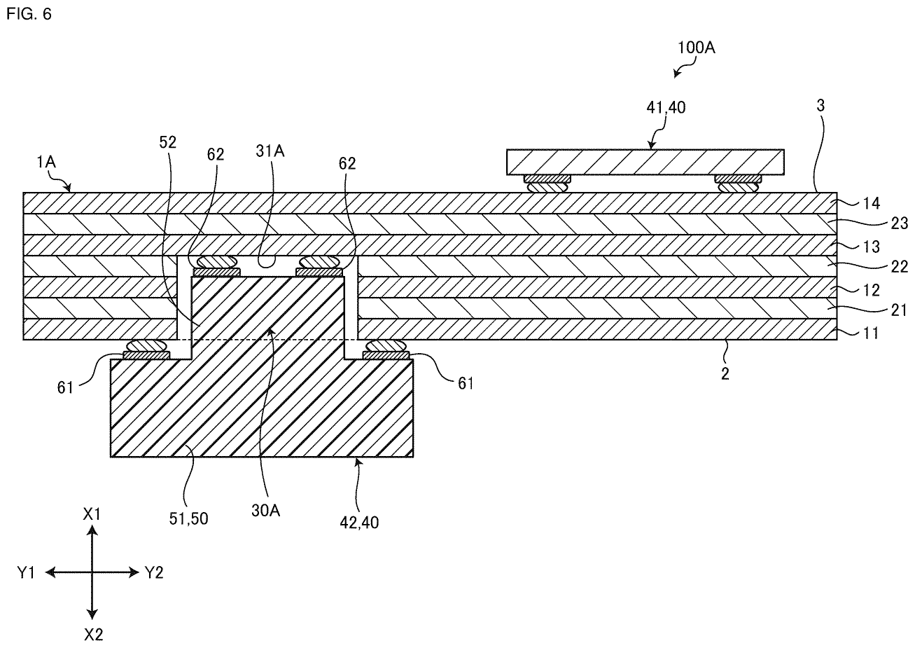

FIG. 6 is a sectional view of an electronic component module according to the second embodiment, taken along an imaginary plane extending in a stacking direction and an array direction. The second embodiment provides an electronic component module 100A in common with embodiment 1 in that a multilayer wiring board 1A includes a first wiring layer (front surface wiring layer) 11 provided with a hole 30A and that a third wiring layer 13 constitutes a bottom surface 31A. A filter device 42 is in common with embodiment 1 in that an outer contour portion body 51 is disposed on the first wiring layer 11 and that a projection 52 is disposed in the hole 30A. The second embodiment is in common with embodiment 1 in that a first electrode 61 is connected to the first wiring layer (front surface wiring layer) 11 and that a second electrode 62 is connected to the third wiring layer (bottom surface wiring layer) 13.

The multilayer wiring board 1A according to the second embodiment is, however, different from the multilayer wiring board 1 according to the first embodiment in that the multilayer wiring board 1A includes no fourth insulating layer 24. Accordingly, a fourth wiring layer 14 is disposed closest to an end in the first direction X1 among a plurality of wiring layers 10, to serve as a rear surface wiring layer constituting a rear surface 3 of the multilayer wiring board 1A. The second embodiment is different from the first embodiment in that an integrated circuit 41 is disposed on the fourth wiring layer 14 (rear surface wiring layer).

Also in the electronic component module 100A according to the second embodiment, the filter device 42 projecting in a second direction X2 from a front surface 2 accordingly has a small projecting amount. Similarly to the first embodiment, the second embodiment thus achieves a reduction in size of the electronic component module 100A.

The embodiment has been described above. The present disclosure is, however, not limited to the exemplification according to the embodiment. For example, the present embodiment provides the two electronic components 40. However, the present disclosure has only to provide at least one electronic component 40.

Furthermore, the first electrode 61 connected to the first LC filter (first electric circuit) 44 is entirely provided on the first facing surface 53 in the present embodiment. However, the first electrode 61 may alternatively be disposed partially on the first facing surface 53 and partially on the second facing surface 54 in the present disclosure. In a similar manner, the second electrode 62 may alternatively be disposed partially on the first facing surface 53 and partially on the second facing surface 54.

The filter device 42 having the two functions (two electric circuits) exemplifies the electronic component 40 according to the present embodiment. However, the present disclosure may alternatively provide an electronic component having a single function or an electronic component having three or more functions. When the electronic component 40 has a single function (electric circuit), a plurality of electrodes connected to the single electric circuit is disposed partially on the first facing surface 53 and partially on the second facing surface 54.

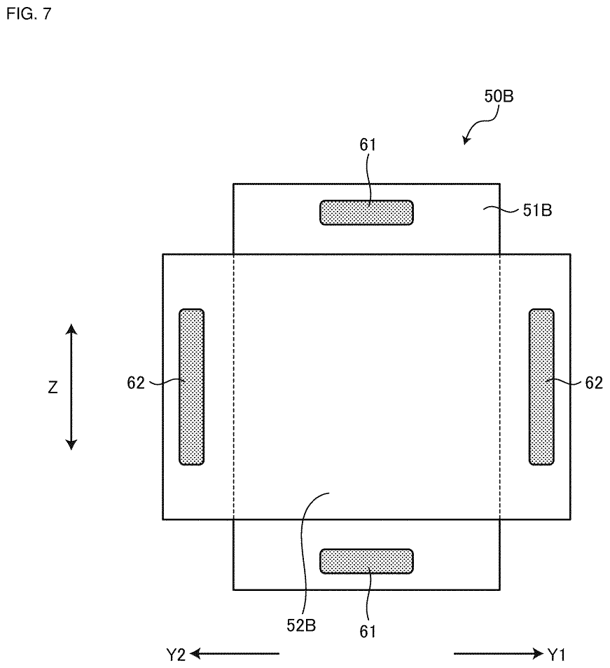

FIG. 7 is a view from a direction opposing the second facing surface of an electronic component according to a variation. The outer contour portion body 51 according to the embodiment is larger than the projection 52 in sizes in the array direction (the first array direction Y1 and the second array direction Y2) and in the width direction Z. However, the present disclosure is not limited to this configuration. As shown in FIG. 7, there may be exemplarily provided an outer contour portion 50B including an outer contour portion body 51B and a projection 52B that is larger than the outer contour portion body 51B in size in the array direction (the first array direction Y1 and the second array direction Y2). That is, the present disclosure does not particularly restrict the sizes of the outer contour portion body and the projection.

The outer contour portion body 51 and the projection 52 according to the embodiment each have the oblong shape when viewed in the stacking direction. However, the outer contour portion body and the projection according to the present disclosure may each have a polygonal shape such as a triangular shape, or a circular shape, when viewed in the stacking direction.

The present disclosure may be achieved by combining the following configurations.
(1) An electronic component module including an electronic component; and a multilayer wiring board disposed in a first direction of the electronic component and including a surface positioned in a second direction opposing the first direction as a disposition surface provided with the electronic component. The multilayer wiring board includes a plurality of wiring layers and a plurality of insulating layers stacked alternately in the first direction. The disposition surface is provided with a hole. The plurality of wiring layers includes a front surface wiring layer constituting the disposition surface, and a bottom surface wiring layer constituting a bottom surface of the hole. The electronic component includes an electric circuit, an outer contour portion containing the electric circuit and forming an outer contour of the electronic component, and an electrode provided on an outer surface of the outer contour portion and connecting the electric circuit and the wiring layers. The outer contour portion includes an outer contour portion body disposed on the front surface wiring layer, a first facing surface constituting a surface in the first direction of the outer contour portion body and facing the front surface wiring layer, a projection projecting in the first direction from the outer contour portion body and disposed in the hole, and a second facing surface constituting an end surface in the first direction of the projection and facing the bottom surface wiring layer. The electrode includes a first electrode provided on the first facing surface and connected to the front surface wiring layer, and a second electrode provided on the second facing surface and connected to the bottom surface wiring layer.
(2) The electronic component module according to (1), in which the electric circuit includes a first electric circuit, and a second electric circuit not connected to the first electric circuit. The first electrode connects the first electric circuit and the front surface wiring layer, and the second electrode connects the second electric circuit and the bottom surface wiring layer.
(3) The electronic component module according to (2), in which the first electric circuit is a first LC filter, the second electric circuit is a second LC filter, and the first LC filter and the second LC filter are different from each other in pass band.
(4) The electronic component module according to (2), in which the first electric circuit is a first LC filter, the second electric circuit is a second LC filter, and the first LC filter and the second LC filter are identical in pass band.
(5) The electronic component module according to any one of (1) to (4), in which the outer contour portion is made of a resin material, and the outer contour body portion and the projection are integrated with each other.
(6) The electronic component module according to any one of (1) to (5), the electronic component module further including an integrated circuit disposed on the front surface wiring layer.
(7) The electronic component module according to any one of (1) to (5), in which the plurality of wiring layers includes a rear surface wiring layer disposed closest to an end in the first direction among the plurality of wiring layers, to constitute a rear surface of the multilayer wiring board, and the rear surface wiring layer is provided with an integrated circuit.

What is claimed is:

1. An electronic component module comprising:
an electronic component; and
a multilayer wiring board extending in a first direction of the electronic component and including a surface positioned in a second direction opposing the first direction as a disposition surface having the electronic component, wherein
the multilayer wiring board includes a plurality of wiring layers and a plurality of insulating layers stacked alternately in the first direction,
the disposition surface has a hole,
the plurality of wiring layers includes
a front surface wiring layer configuring the disposition surface, and
a bottom surface wiring layer configuring a bottom surface of the hole,
the electronic component includes
an electric circuit,
an outer contour portion including the electric circuit and defining an outer contour of the electronic component, and
an electrode on an outer surface of the outer contour portion and connecting the electric circuit and the wiring layers,
the outer contour portion includes
an outer contour portion body on the front surface wiring layer,
a first facing surface configuring a surface in the first direction of the outer contour portion body and facing the front surface wiring layer,
a projection projecting in the first direction from the outer contour portion body and being in the hole, and
a second facing surface defining an end surface in the first direction of the projection and facing the bottom surface wiring layer, and
the electrode includes
a first electrode on the first facing surface and connected to the front surface wiring layer, and
a second electrode on the second facing surface and connected to the bottom surface wiring layer.

2. The electronic component module according to claim 1, wherein
the electric circuit includes
a first electric circuit, and
a second electric circuit not connected to the first electric circuit,
the first electrode connects the first electric circuit and the front surface wiring layer, and
the second electrode connects the second electric circuit and the bottom surface wiring layer.

3. The electronic component module according to claim 2, wherein
the first electric circuit is a first LC filter,
the second electric circuit is a second LC filter, and
the first LC filter and the second LC filter are different from each other in pass band.

4. The electronic component module according to claim 2, wherein
the first electric circuit is a first LC filter,
the second electric circuit is a second LC filter, and
the first LC filter and the second LC filter are identical in pass band.

5. The electronic component module according to claim 1, wherein
the outer contour portion includes a resin material, and
the outer contour body portion and the projection are integrated with each other.

6. The electronic component module according to claim 1, further comprising:
an integrated circuit on the front surface wiring layer.

7. The electronic component module according to claim 1, wherein
the plurality of wiring layers includes a rear surface wiring layer that is closest to an end in the first direction among the plurality of wiring layers, to define a rear surface of the multilayer wiring board, and
the rear surface wiring layer includes an integrated circuit.

8. The electronic component module according to claim 2, wherein
the outer contour portion includes a resin material, and
the outer contour body portion and the projection are integrated with each other.

9. The electronic component module according to claim 3, wherein
the outer contour portion includes a resin material, and
the outer contour body portion and the projection are integrated with each other.

10. The electronic component module according to claim 4, wherein
the outer contour portion includes a resin material, and
the outer contour body portion and the projection are integrated with each other.

11. The electronic component module according to claim 2, further comprising:
an integrated circuit on the front surface wiring layer.

12. The electronic component module according to claim 3, further comprising:
an integrated circuit on the front surface wiring layer.

13. The electronic component module according to claim 4, further comprising:
an integrated circuit on the front surface wiring layer.

14. The electronic component module according to claim 5, further comprising:
an integrated circuit on the front surface wiring layer.

15. The electronic component module according to claim 8, further comprising:
an integrated circuit on the front surface wiring layer.

16. The electronic component module according to claim 9, further comprising:
an integrated circuit on the front surface wiring layer.

17. The electronic component module according to claim 2, wherein
the plurality of wiring layers includes a rear surface wiring layer that is closest to an end in the first direction among the plurality of wiring layers, to define a rear surface of the multilayer wiring board, and
the rear surface wiring layer includes an integrated circuit.

18. The electronic component module according to claim 3, wherein
the plurality of wiring layers includes a rear surface wiring layer that is closest to an end in the first direction among the plurality of wiring layers, to define a rear surface of the multilayer wiring board, and
the rear surface wiring layer includes an integrated circuit.

19. The electronic component module according to claim 4, wherein
the plurality of wiring layers includes a rear surface wiring layer that is closest to an end in the first direction among the plurality of wiring layers, to define a rear surface of the multilayer wiring board, and
the rear surface wiring layer includes an integrated circuit.

20. The electronic component module according to claim 5, wherein
the plurality of wiring layers includes a rear surface wiring layer that is closest to an end in the first direction among the plurality of wiring layers, to define a rear surface of the multilayer wiring board, and
the rear surface wiring layer includes an integrated circuit.
